(19) United States
(12) Patent Application Publication
(10) Pub. No.: US 2007/0207348 A1
(43) Pub. Date: Sep. 6, 2007

(54) PERPENDICULAR MAGNETIC RECORDING MEDIUM, METHOD OF MANUFACTURING THE SAME, AND MAGNETIC STORAGE UNIT

(75) Inventor: Ryoichi MUKAI, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/531,017

(22) Filed: Sep. 12, 2006

(30) Foreign Application Priority Data
Mar. 2, 2006 (JP) 2006-056635

(51) Int. Cl. G11B 5/66; C23C 14/00

(52) U.S. Cl. 428/831.2; 428/832; 204/192.2

(57) ABSTRACT

A perpendicular magnetic recording medium is disclosed that includes a substrate, an underlayer formed of one of Ru and a Ru alloy on the substrate, and a recording layer formed on the underlayer. The underlayer includes multiple crystal grains extending in a direction perpendicular to the surface of the substrate, the crystal grains being separated from each other by a first air gap part. The recording layer includes multiple magnetic particles deposited on the crystal grains of the underlayer, the magnetic particles being separated from each other by a second air gap part.

### CROSS-REFERENCE TO RELATED APPLICATION

The present application is based on Japanese Priority Patent Application No. 2006-056635, filed on Mar. 2, 2006, the entire contents of which are hereby incorporated by reference.

### BACKGROUND OF THE INVENTION

1. Field of the Invention

The present invention relates generally to perpendicular magnetic recording media, methods of manufacturing the same, and magnetic storage units including the same, and more particularly to a perpendicular magnetic recording medium having a magnetic layer in which magnetic particles are separated from one another, a method of manufacturing the same, and a magnetic storage unit including the same.

2. Description of the Related Art

Magnetic storage units, for example, hard disk drive units, which are digital signal recorders that can be provided with large capacity because of their low memory unit price per bit, have been widely used for apparatuses such as personal computers lately. A further increase in the capacity of the hard disk drive unit is desired because of a dramatically increasing demand generated by its use in digital-acoustic-image-related apparatuses, and for recording video signals.

In order to achieve both large capacity and low price, the number of magnetic recording media in a unit is reduced by increasing the recording density of the magnetic recording medium. Thereby, the number of magnetic heads is reduced, so that the number of components is reduced, thus resulting in low price.

One method of increasing the recording density of the magnetic recording medium is to improve signal-to-noise (SN) ratio by achieving higher resolution and lower noise. Conventionally, noise reduction has been promoted by miniaturizing the magnetic particles forming a recording layer and magnetically isolating the magnetic particles.

Perpendicular magnetic recording media are formed by stacking a soft magnetic underlayer formed of a soft magnetic material on a substrate and stacking a recording layer on the soft magnetic underlayer. Usually, the recording layer is formed of a CoCr-based alloy. The CoCr-based alloy is formed by sputtering while applying heat to the substrate, so that non-magnetic Cr is segregated at the grain boundary between Co-rich magnetic particles of the CoCr-based alloy, thereby separating and magnetically isolating the magnetic particles from one another.

On the other hand, the soft magnetic underlayer forms the magnetic path of magnetic flux flowing into a magnetic head at the time of reproduction. In a crystalline soft magnetic material, spike noise is generated because of magnetic domains. Therefore, the soft magnetic underlayer is formed of an amorphous or microcrystalline body, for which it is difficult to form magnetic domains. Accordingly, the heating temperature at the time of forming the recording layer is restricted in order to avoid crystallization of the soft magnetic underlayer.

There is proposed a recording layer that improves SN ratio by reducing the magnetic interactions between the magnetic particles of the recording layer by separating the magnetic particles with a non-magnetic material. This recording layer has a columnar structure where the magnetic particles of a CoCr-based alloy grow perpendicularly on the substrate surface, and the spaces around the magnetic particles are filled with a non-magnetic oxide such as SiO₂ or ZrO₂. Such a recording layer structure is generally called a granular structure or a columnar granular structure.

Further, there is proposed a perpendicular magnetic recording medium in which the crystal grains of an underlayer are spatially separated from one another, so that the magnetic particles of a recording layer of a granular structure growing on the underlayer are further separated from one another uniformly (see, for example, Japanese Laid-Open Patent Application No. 2005-353256).

A recording layer having a granular structure is formed in a film formation chamber by sputtering, using sputtering targets of a CoCr-based alloy and an oxide such as SiO₂ and sputtering the sputtering targets. The oxide such as SiO₂ is likely to become particles or clusters. Once becoming particles or clusters, the oxide is likely to float in the film formation chamber so as to adhere to and contaminate a substrate surface. In this case, projection-like defects are formed on the surface of a perpendicular magnetic recording medium after formation of each of its layers. This causes reduction in the production yield, and further causes a problem such as a head crash of a magnetic storage unit, which may reduce reliability.

### SUMMARY OF THE INVENTION

Embodiments of the present invention may solve or reduce one or more of the above problems.

In an embodiment of the present invention, there is provided a perpendicular magnetic recording medium in which the above-described problems are solved.

In an embodiment of the present invention, there are provided a perpendicular magnetic recording medium capable of high-density recording, avoiding a decrease in the production yield, and improving the reliability of a magnetic storage unit; a method of manufacturing the same, and a magnetic storage unit including the same.

According to one aspect of the present invention, there is provided a perpendicular magnetic recording medium including a substrate, an underlayer formed of one of Ru and a Ru alloy on the substrate, and a recording layer formed on the underlayer, wherein the underlayer includes a plurality of crystal grains extending in a direction perpendicular to a surface of the substrate, the crystal grains being separated from each other by a first air gap part; and the recording layer includes a plurality of magnetic particles deposited on the crystal grains of the underlayer, the magnetic particles being separated from each other by a second air gap part.

According to one aspect of the present invention, the crystal grains of an underlayer grow, being separated from one another by an air gap part, and the magnetic particles of the recording layer grow thereon. Therefore, the magnetic particles are disposed, being separated from one another. Therefore, it is possible to reduce medium noise by suppressing the magnetic interactions exerted between the individual magnetic particles. As a result, the SN ratio of the perpendicular magnetic recording medium is improved, thus enabling recording to be performed with still higher density. On the other hand, the magnetic particles of a recording layer are separated from one another by an air gap part. Accordingly, compared with the conventional perpendicular magnetic recording medium containing oxide, nitride, and/or oxynitride (in the specification, collectively referred to as “oxide, etc.”) in its recording layer, it is possible to realize a highly reliable perpendicular magnetic recording medium because it is possible to prevent the surface of the recording layer from being contaminated by oxide, etc. Further, the perpendicular magnetic recording medium makes it possible to prevent a decrease in the production yield due to the material of the recording layer.

Another underlayer may be provided between the substrate and the underlayer, and the other underlayer may be formed of a polycrystalline film of crystal grains of Ru or a Ru alloy coupled to each other through a grain boundary part. The other underlayer formed of the crystal grains of Ru or a Ru alloy and the grain boundary part is provided between the substrate and the underlayer. Since the other underlayer is a continuous polycrystalline film, the other underlayer has good crystal orientation. This promotes the crystal orientation of the crystal grains of the underlayer, thus further improving the crystal orientation of the magnetic particles of the recording layer. As a result, magnetic characteristics such as perpendicular coercive force and rectangularity ratio are improved so as to increase reproduction output at high recording density, thus resulting in better recording and reproduction characteristics. Accordingly, it is possible to perform recording with higher density.

According to one aspect of the present invention, there is provided a magnetic storage unit including a recording and reproduction part including a magnetic head; and a perpendicular magnetic recording medium according to one embodiment of the present invention.

According to one aspect of the present invention, it is possible to provide a highly reliable magnetic storage unit having a good SN ratio.

According to one aspect of the present invention, there is provided a method of manufacturing a perpendicular magnetic recording medium, including the steps of: (a) forming an underlayer on a substrate; and (b) forming a recording layer on the underlayer, wherein step (a) forms the underlayer by sputtering at a deposition rate lower than or equal to 2 nm/s and at an atmospheric gas pressure higher than or equal to 2.66 Pa using a sputtering target of one of Ru and a Ru alloy; and step (b) deposits only a material formed of a ferromagnetic material.

According to one aspect of the present invention, a granular structure is formed in a recording layer without using a non-magnetic material such as oxide. Therefore, a film formation chamber is prevented from being contaminated by oxide, etc. Accordingly, the surface of the recording layer is prevented from being contaminated by oxide, etc., so that it is possible to avoid a decrease in the yield in a surface defect inspection of perpendicular magnetic recording media. Accordingly, it is possible to avoid a decrease in the production yield. Further, since it is possible to prevent the surface of the recording layer from being contaminated by oxide, etc., it is possible to provide a highly reliable perpendicular magnetic recording medium.

Thus, according to embodiments of the present invention, it is possible to provide a perpendicular magnetic recording medium capable of improving SN ratio, avoiding a decrease in the production yield, and improving the reliability of a magnetic storage unit; a method of manufacturing the same; and a magnetic storage unit including the same.

### BRIEF DESCRIPTION OF THE DRAWINGS

Other objects, features and advantages of the present invention will become more apparent from the following detailed description when read in conjunction with the accompanying drawings, in which:

FIG. 1 is a cross-sectional view of a perpendicular magnetic recording medium of a first example according to a first embodiment of the present invention;

FIG. 2 is a schematic enlarged view of part of the perpendicular magnetic recording medium of the first example according to the first embodiment of the present invention;

FIG. 3 is a cross-sectional view of a perpendicular magnetic recording medium of a second example according to the first embodiment of the present invention;

FIG. 4 is a schematic enlarged view of part of the perpendicular magnetic recording medium of the second example according to the first embodiment of the present invention;

FIG. 5 is a table showing the magnetic characteristics of the perpendicular magnetic recording media of Implementation Examples 1 through 3 and a comparative example according to the first embodiment of the present invention;

FIG. 6A is a cross-sectional TEM photograph of a perpendicular magnetic recording medium of an implementation example according to the first embodiment of the present invention;

FIG. 6B is a diagram for illustrating FIG. 6A according to the first embodiment of the present invention; and

FIG. 7 is a plan view of part of a magnetic storage unit according to a second embodiment of the present invention.

### DETAILED DESCRIPTION OF THE PREFERRED EMBODIMENTS

A description is given, with reference to the accompanying drawings, of embodiments of the present invention.

### First Embodiment

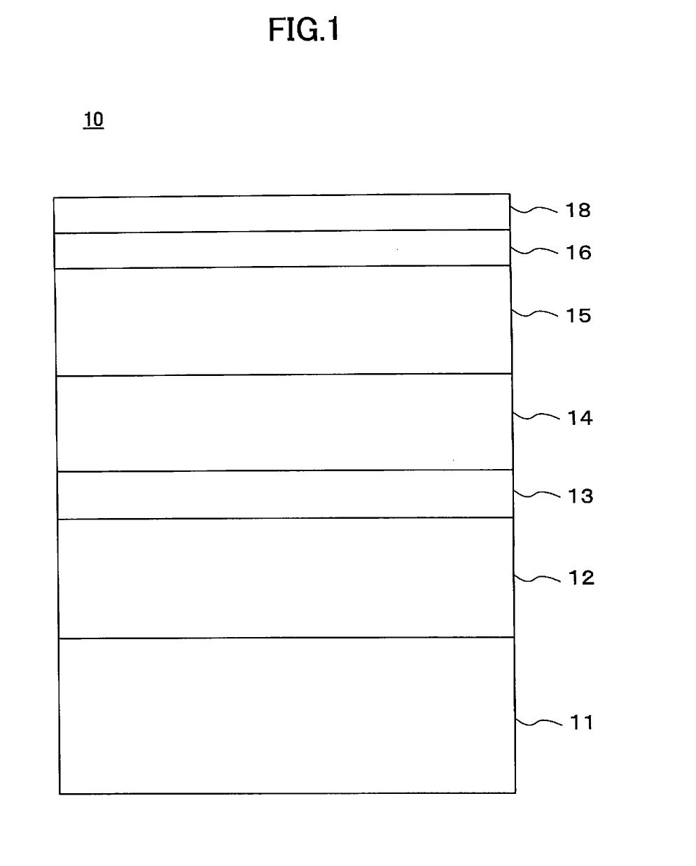

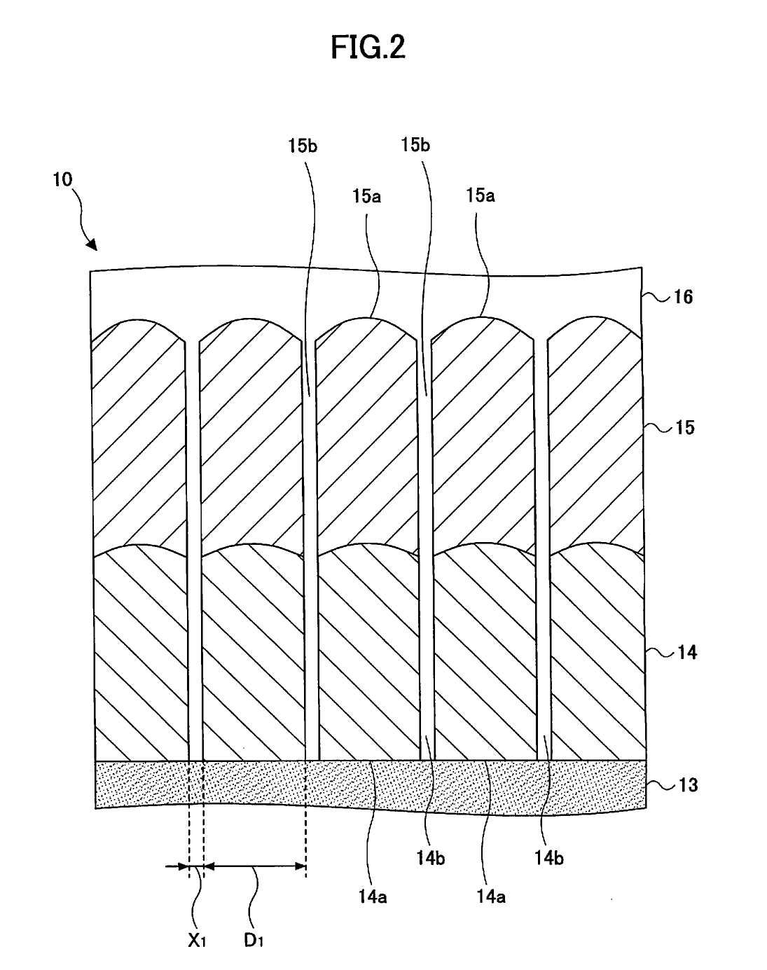

FIG. 1 is a schematic cross-sectional view of a perpendicular magnetic recording medium 10 of a first example according to a first embodiment of the present invention. FIG. 2 is a schematic enlarged view of part of the perpendicular magnetic recording medium 10 shown in FIG. 1.

Referring to FIGS. 1 and 2, the perpendicular magnetic recording medium 10 of the first example according to the first embodiment includes a substrate 11, a soft magnetic underlayer 12, a seed layer 13, an underlayer 14, a recording layer 15, a protection film 16, and a lubricating layer 18. The soft magnetic underlayer 12, the seed layer 13, the underlayer 14, the recording layer 15, the protection film 16, and the lubricating layer 18 are stacked in order on the substrate 11. As described in detail below, the perpendicular magnetic recording medium 10 has a configuration where crystal grains 14a of the underlayer 14 are disposed in the substrate in-plane direction with an air gap part 14b intervening therebetween, and magnetic particles 15a of the recording layer 15 are disposed thereon in the substrate in-plane direction with an air gap part 15b intervening therebetween.

The substrate 11 is, for example, a plastic substrate, a crystallized glass substrate, a toughened glass substrate, a Si substrate, or an aluminum alloy substrate. Further, if the perpendicular magnetic recording medium 10 is shaped like a tape, a film of polyester (PET), polyethylene naphthalate (PEN), or polyimide (PI) having good heat resistance may be employed. Since no substrate heating is required in the present invention, it is possible to employ these resin substrates.

The soft magnetic underlayer 12 is, for example, 50 nm to 2 μm in film thickness, and formed of an amorphous or microcrystalline soft magnetic material including at least one element selected from Fe, Co, Ni, Al, Si, Ta, Ti, Zr, Hf, V, Nb, C, and B. Further, the soft magnetic underlayer 12 is not limited to a single layer, and may be stacked multiple layers.

Further, it is preferable that the soft magnetic underlayer 12 be formed of a soft magnetic material whose saturation flux density is higher than or equal to 1.0 T in terms of capability of concentrating a recording magnetic field. Examples of such a soft magnetic material include FeSi, FeAlSi, FeTaC, CoNbZr, CoCrNb, NiFeNb, and Co. Further, it is preferable that the soft magnetic underlayer 12 be higher in high-frequency magnetic permeability in terms of writability at high transfer rate. The soft magnetic underlayer 12 is formed by plating, sputtering, vapor deposition, or CVD (chemical vapor deposition).

The seed layer 13 is, for example, 2.0 nm to 10 nm in film thickness, and formed of an amorphous metal of at least one material selected from Ta, Ti, C, Mo, W, Re, Os, Hf, Mg, Pt, and their alloys or of an amorphous metal of NiP. The seed layer 13 orients the c-axes of the crystal grains 14a of the underlayer 14 formed on the seed layer 13 in the directions of film thickness. Further, the seed layer 13 causes the crystal grains 14a of the underlayer 14 to be distributed evenly in the substrate in-plane direction.

Further, it is preferable that the seed layer 13 be formed of Ta in terms of good crystal orientation of the underlayer 14. It is preferable that the seed layer 13 be a single film of the above-described material in terms of proximity of the soft magnetic underlayer 12 and the recording layer 15. It is preferable that the seed layer 13 be 1.0 nm to 5.0 nm in film thickness. The seed layer 13 may be a layered body of stacked films of the above-described material. As described above, it is preferable to provide the seed layer 13. However, the seed layer 13 may be omitted.

The underlayer 14 is formed of the multiple crystal grains 14a formed of Ru or a Ru—X alloy having an hcp (hexagonal close-packed) crystal structure where X is at least one selected from the group of Co, Cr, Fe, Ni, and Mn. Each of the crystal grains 14a has a columnar structure growing in the direction perpendicular to the substrate surface from the surface of the seed layer 13 up to the interface with the recording layer 15. Further, the crystal grains 14a are separated from one another in the substrate in-plane direction by the air gap part 14b. A single crystal grain 14a is formed of a single crystal. Multiple single crystals may be formed in one single crystal grain 14a. In terms of crystal orientation, however, it is preferable that a single crystal grain 14a be formed of a single crystal.

The air gap part 14b of the underlayer 14 is formed upward from the bottom surfaces of the crystal grains 14a up to the interface with the recording layer 15 with the shape of its cross section parallel to the substrate surface being substantially uniform. Alternatively, the air gap part 14b of the underlayer 14 may be formed so as to be wider toward the upper parts of the crystal grains 14a. According to the studies by the inventor of the present invention, it is often observed from cross-sectional TEM (transmission electron microscope) images of the perpendicular magnetic recording medium 10 that the air gap part 14b is wider around the upper halves of the crystal grains 14a than the lower halves thereof. By forming such an underlayer 14, it is possible to suitably separate the magnetic particles 15a of the recording layer 15 formed on the surfaces of the crystal grains 14a from one another. As described in detail below, the underlayer 14 can be formed by setting the atmospheric gas pressure of an inert gas such as Ar gas and the deposition rate of the underlayer 14 within predetermined ranges, respectively.

It is preferable that the average grain size D₁ (FIG. 2) of the crystal grains 14a in the in-plane direction be in the range of 2 nm to 10 nm (more preferably, 5 nm to 10 nm). This results in good controllability of the particle size of the magnetic particles 15a of the recording layer 15 growing on the crystal grains 14a. Further, it is preferable that the average width X₁ (FIG. 2) of the air gap part 14b be in the range of 1 nm to 2 nm. This results in good controllability of the gap between the magnetic particles 15a of the recording layer.

The growth direction of the crystal grains 14a of the underlayer 14 is the (0001) plane of Ru or the Ru—X alloy. If the recording layer 15 is formed of the magnetic particles 15a having an hcp crystal structure, it is possible to orient the c-axes (magnetocrystalline easy axes) of the magnetic particles 15a in the directions perpendicular to the substrate surface. It is preferable that the underlayer 14 be pure Ru in terms of good crystal growth.

Further, it is preferable that the underlayer 14 be in the range of 5 nm to 30 nm in film thickness. If the underlayer 14 is less than 2 nm in film thickness, the underlayer 14 has poor crystallinity. If the underlayer 14 is greater than 30 nm in film thickness, the thickness from the surface of the soft magnetic underlayer 12 to the surface of the lubricating layer 18 increases so as to increase spacing loss in recording and reproduction. Further, problems such as side erasure at the time of recording tend to occur easily. Further, it is preferable that the underlayer 14 be in the range of 3 nm to 16 nm in film thickness in terms of good isolation of the crystal grains 14a. It is more preferable that the underlayer 14 be in the range of 3 nm to 10 nm in film thickness in terms of further avoidance of an increase in spacing loss.

The recording layer 15 is formed of the multiple magnetic particles 15a formed of a ferromagnetic material selected from the group consisting of Ni, Fe, Co, Ni-based alloys, Fe-based alloys, CoCr, CoPt, and CoCr alloys. Examples of CoCr alloys include CoCrTa, CoCrPt, and CoCrPt-M, where M is at least one selected from the group consisting of B, Mo, Nb, Ta, W, and Cu. Each of the magnetic particles 15a has a columnar structure growing in the direction substantially perpendicular to the substrate surface from the surface of the corresponding crystal grain 14a of the underlayer 14. Further, the magnetic particles 15a are separated from one another in the substrate in-plane direction by the air gap part 15b. The magnetic particles 15a of the recording layer 15 grow epitaxially on the corresponding crystal grains 14a of the underlayer 14. Each single magnetic particle 15a is formed on the corresponding single crystal grain 14a. Accordingly, the air gap part 15b of the recording layer 15 is formed so as to communicate with the air gap part 14b of the underlayer 14.

It is preferable that the magnetic particles 15a of the recording layer 15 be formed of a ferromagnetic material selected from the group consisting of CoCr, CoCrTa, CoPt, CoCrPt, and CoCrPt-M. These ferromagnetic materials have an hcp crystal structure, and grow on the (0001) planes of the crystal grains 14a of the underlayer 14 in the direction of the (0001) plane. That is, the c-axes (magnetocrystalline easy axes) of the magnetic particles 15a are oriented perpendicularly to the substrate surface.

Further, it is preferable that the magnetic particles 15a of the recording layer 15 be formed of a ferromagnetic material selected from the group consisting of CoPt, CoCrPt and CoCrPt-M in particular.

If the magnetic particles 15a are formed of CoCrPt-M, the Co content is 50 at % to 80 at %, the Pt content is 15 at % to 30 at %, and the M density is greater than 0 at % and less than or equal to 20 at % with the rest being the Cr content. By thus increasing the Pt content compared with the conventional perpendicular magnetic recording medium, it is possible to increase an anisotropic magnetic field and thereby increase coercive force perpendicular to the substrate surface.

In terms of suitability for achieving high recording density, the recording layer 15 is preferably in the range of 3 nm to 15 nm, and more preferably, in the range of 5 nm to 10 nm, in film thickness.

Referring back to FIG. 1, the protection film 16 is not limited in particular, and is selected from, for example, amorphous carbon, hydrogenated carbon, carbon nitride, aluminum oxide, etc., of 0.5 nm to 15 nm in film thickness.

The lubricating layer 18 is not limited in particular. For example, a lubricant having a main chain of perfluoropolyether of 0.5 nm to 5 nm in film thickness may be employed. The lubricating layer 18 may be either provided or not provided depending on the material of the protection film 16.

In the perpendicular magnetic recording medium 10 of the first example according to the first embodiment, the crystal grains 14a of the underlayer 14 grow, being separated from one another by the air gap part 14b, and the magnetic particles 15a of the recording layer 15 grow thereon. Therefore, the magnetic particles 15a are separated from one another. As a result, the magnetic interactions exerted between the individual magnetic particles 15a are suppressed so that medium noise can be reduced. Consequently, it is possible to improve the SN ratio of the perpendicular magnetic recording medium 10. On the other hand, since the magnetic particles 15a of the recording layer 15 are separated from one another by the air gap part 15b, it is possible to prevent the surface of the recording layer 15 from being contaminated by oxide, etc. Accordingly, the perpendicular magnetic recording medium 10 having higher reliability than the conventional perpendicular magnetic recording medium containing oxide, etc., in its recording layer can be realized. Further, the perpendicular magnetic recording medium 10 can avoid a decrease in the production yield due to the material of the recording layer 15.

Next, a description is given, with reference to FIG. 1, of a method of manufacturing the perpendicular magnetic recording medium 10 of the first example according to the first embodiment.

First, after cleaning and drying the surface of the substrate 11, the soft magnetic underlayer 12 is formed on the substrate 11 by electroless plating, electroplating, sputtering, or vacuum evaporation.

Next, the seed layer 13 is formed on the soft magnetic underlayer 12 with a sputtering apparatus using a sputtering target formed of the above-described material. For the sputtering apparatus, it is preferable to use an ultrahigh vacuum sputtering apparatus that can be evacuated to 10⁻⁷ Pa in advance. Specifically, the seed layer 13 is formed at a pressure of 0.4 Pa in an Ar gas atmosphere by DC magnetron sputtering. At this point, it is preferable to apply no heat to the substrate 11. It is possible to prevent crystallization of the soft magnetic underlayer 12 or an increase in the size of the microcrystals thereof. The substrate 11 may be heated to temperatures, such as 150° C. or less, that do not cause crystallization of the soft magnetic underlayer 12 or an increase in the size of the microcrystals thereof. It is preferable that the lower limit of the substrate temperature be 20° C. in that no heating apparatus or cooling apparatus is required. Further, the soft magnetic underlayer 12 may be formed by cooling the substrate 11. For example, the substrate 11 may be −100° C. in temperature. Further, if there are no apparatus restrictions, the substrate 11 may be cooled to temperatures below −100° C. The temperature conditions of the substrate 11 in the process of forming the underlayer 14 and the process of forming the recording layer 15 are the same as in the process of forming the seed layer 13.

Next, the underlayer 14 is formed on the seed layer 13 with a sputtering apparatus using a sputtering target formed of Ru or the above-described Ru—X alloy. Specifically, the underlayer 14 is formed in an inert gas atmosphere such as an Ar gas atmosphere by DC magnetron sputtering, for example. The deposition rate is lower than or equal to 2 nm/s and the atmospheric gas pressure is higher than or equal to 2.66 Pa (20 mTorr) at the time of film formation. By thus setting the deposition rate and the atmospheric gas pressure, it is possible to form the underlayer 14 of the above-described crystal grains 14a and air gap part 14b. Here, if the deposition rate is higher than 2 nm/s, the air gap part 14b is not formed, and a continuous body of crystal grains and a grain boundary part (described below in the next embodiment) is formed. Further, if the atmospheric gas pressure is lower than 2.66 Pa (20 mTorr), the air gap part 14b is not formed, either, and a continuous body of crystal grains and a grain boundary part (described below in the next embodiment) is also formed.

The deposition rate is preferably 0.1 nm/sec or higher in terms of prevention of excessive reduction in production efficiency. Further, the atmospheric gas pressure is preferably 26.6 Pa (200 mTorr) or lower. If the atmospheric gas pressure is higher than 26.6 Pa, the inert gas tends to be captured in the crystal grains 14a to reduce their crystallinity. For the same reason as described above, it is preferable to apply no heat to the substrate 11 at the time of forming the underlayer 14.

Next, the recording layer 15 is formed on the underlayer 14 with a sputtering apparatus using a sputtering target formed of the above-described material. Specifically, the recording layer 15 is formed in an inert gas atmosphere, for example, in an Ar gas atmosphere, by DC magnetron sputtering using a sputtering target of the magnetic material of the magnetic particles 15a. The magnetic particles 15a of the recording layer 15 grow on the surfaces of the crystal grains 14a of the underlayer 14, so that the air gap part 15b is formed around each magnetic particle 15a. Accordingly, the magnetic particles 15a are separated from one another by the air gap part 15b. The atmospheric gas pressure at the time of film formation is preferably in the range of 2.00 Pa to 8.00 Pa. Further, the deposition rate of the recording layer 15 is preferably 0.5 nm/s or lower in terms of promotion of isolation of the magnetic particles 15a of the recording layer 15 during their formation. Further, the deposition rate of the recording layer 15 is more preferably 0.2 nm/s or lower in terms of promotion of further isolation of the magnetic particles 15a of the recording layer 15 during their formation.

From the process of forming the above-described seed layer 13 to the process of forming the recording layer 15, it is preferable, in terms of surface cleanness, to retain the layered structure in a vacuum or a film formation atmosphere with each layer formed at its surface.

Next, the protection film 16 is formed on the recording layer 15 using sputtering, CVD, or FCA (Filtered Cathodic Arc). Next, the lubricating layer 18 is applied on the surface of the protection film 16 by a pulling method, spin coating, or liquid level lowering. Thereby, the perpendicular magnetic recording medium 10 of the first example according to the first embodiment is formed.

In the above-described processes of forming the seed layer 13, the underlayer 14, and the recording layer 15, DC magnetron sputtering is employed by way of example. Alternatively, other sputtering methods such as RF sputtering, and vacuum evaporation may be used.

According to the manufacturing method of the perpendicular magnetic recording medium 10 of the first example, by setting the deposition rate and the atmospheric gas pressure at the time of forming the underlayer 14 within respective predetermined ranges and thereby forming the crystal grains 14a of the underlayer 14 so that the crystal grains 14a are separated from one another by the air gap part 14b, it is possible to form a structure where the magnetic particles 15a of the recording layer 15 are separated by the air gap part 15b. Accordingly, since the recording layer 15 in which the magnetic particles 15a are separated by the air gap part 15b can be formed without using oxide, etc., such as SiO₂, it is possible to prevent the recording layer 15 from being contaminated by oxide, etc., in the film formation chamber of a sputtering apparatus in which the recording layer 15 is formed. As a result, it is possible to prevent contamination of the surface of the recording layer 15, so that it is possible to prevent a decrease in the production yield and further to manufacture a highly reliable perpendicular magnetic recording medium.

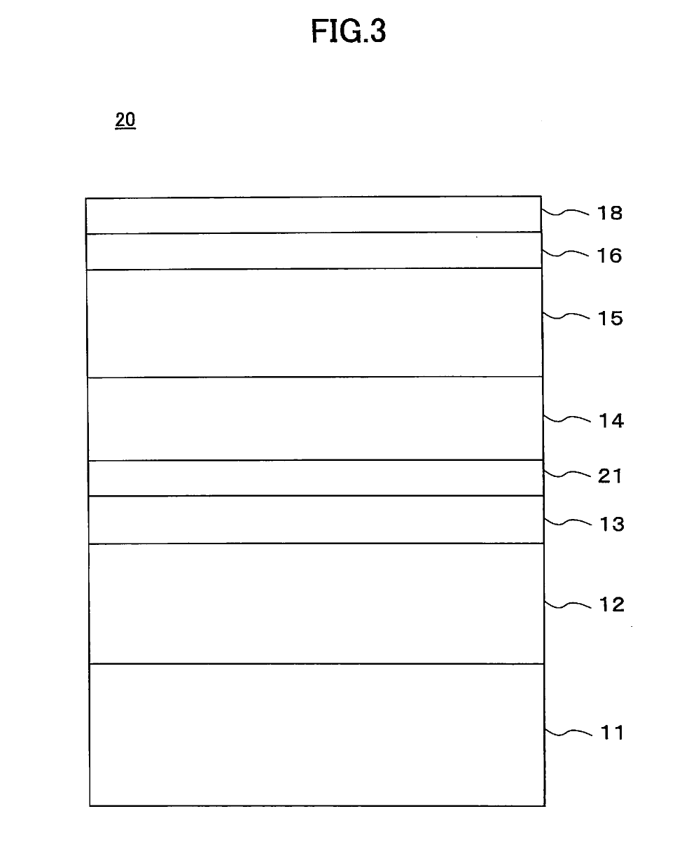

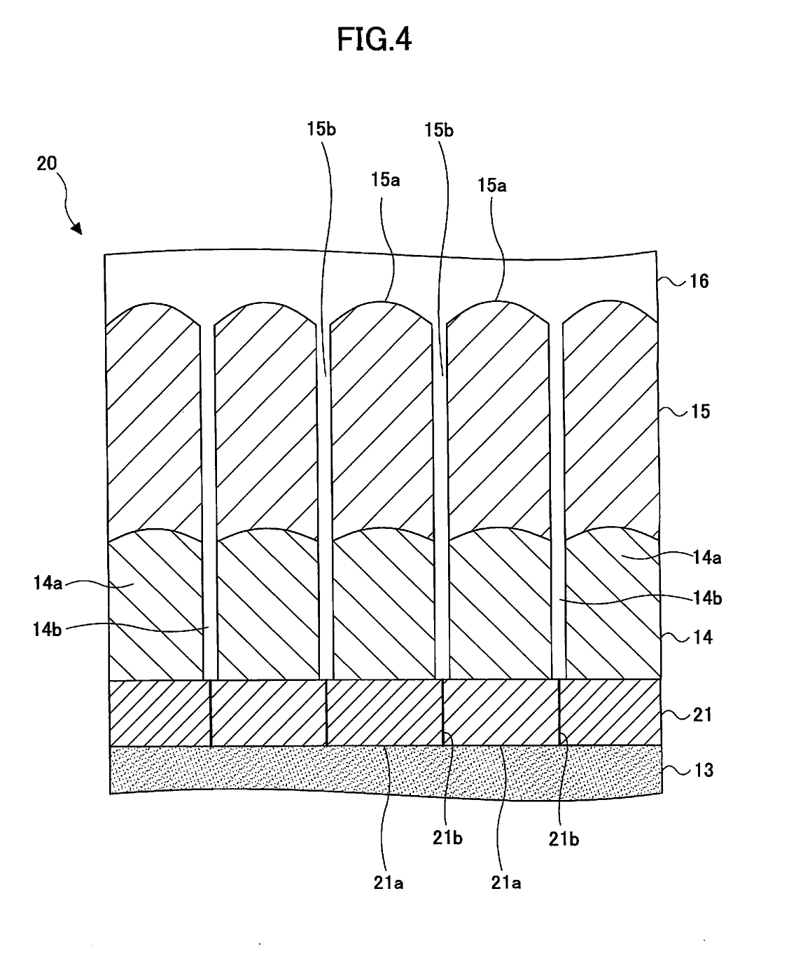

Next, a description is given, with reference to FIGS. 3 and 4, of a perpendicular magnetic recording medium 20 of a second example according to the first embodiment. The perpendicular magnetic recording medium 20 of the second example is the same as the perpendicular magnetic recording medium 10 of the first example except that another underlayer (first underlayer) 21 is further provided between the seed layer 13 and the underlayer (second underlayer) 14.

FIG. 3 is a cross-sectional view of the perpendicular magnetic recording medium 20 of the second example according to the first embodiment. FIG. 4 is a schematic enlarged view of part of the perpendicular magnetic recording medium 20 of the second example. In the drawings, the elements corresponding to those described above are referred to by the same numerals, and a description thereof is omitted. In the perpendicular magnetic recording medium 20 of the second example, the second underlayer, which is the same as the underlayer 14 (shown in FIGS. 1 and 2) of the perpendicular magnetic recording medium 10 of the first example, is referred to by the same numeral 14, and a description thereof is omitted.

Referring to FIGS. 3 and 4, the perpendicular magnetic recording medium 20 of the second example includes the substrate 11, the soft magnetic underlayer 12, the seed layer 13, the first underlayer 21, the second underlayer 14, the recording layer 15, the protection film 16, and the lubricating layer 18. The soft magnetic underlayer 12, the seed layer 13, the first underlayer 21, the second underlayer 14, the recording layer 15, the protection film 16, and the lubricating layer 18 are stacked in order on the substrate 11. In the perpendicular magnetic recording medium 20, the first underlayer 21, which is a continuous polycrystalline film of crystal grains in close contact with one another, formed of the same material as the second underlayer 14, is provided between the seed layer 13 and the second underlayer 14. Since the first underlayer 21 is a continuous polycrystalline film, the first underlayer 21 has good crystallinity. Therefore, the first underlayer 21 improves the crystal orientation of the crystal grains 14a of the second underlayer 14, so that the crystal orientation of the magnetic particles 15a of the recording layer 15 is further improved.

The first underlayer 21, which is formed of the same material as the second underlayer 14, includes crystal grains 21a and a grain boundary part 21b. The crystal grains 21a are substantially the same as the crystal grains 14a of the second underlayer 14. The grain boundary part 21b is the grain boundary of the crystal grains 21a. That is, the grain boundary part 21b is formed of atoms (amorphous or microcrystalline) of Ru or a Ru—X alloy where X is at least one selected from the group of Co, Cr, Fe, Ni, and Mn. Since the first underlayer 21 thus forms a continuous film of the crystal grains 14a coupled to one another through the grain boundary part 14b, the first underlayer 21 has good crystallinity, and the crystal orientation of its (0001) plane is perpendicular to the substrate surface. Accordingly, the second underlayer 14 has good crystallinity near the interface with the first underlayer 21. Therefore, the crystal grains 14a of the second underlayer 14 have better crystallinity and crystal orientation, and further, the magnetic particles 15a of the recording layer 15 have better crystallinity and crystal orientation.

The first underlayer 21 is in the range of 2 nm to 14 nm in film thickness. The total film thickness of the first underlayer 21 and the second underlayer 14 is in the range of 4 nm to 16 nm, and preferably, in the range of 4 nm to 11 nm in terms of spacing loss.

Next, a description is given, with reference to FIGS. 3 and 4, of a method of forming the first underlayer 21. The first underlayer 21 is formed on the seed layer 13 with a sputtering apparatus using a sputtering target formed of Ru or the above-described Ru—X alloy. Specifically, the first underlayer 21 is formed in an inert gas atmosphere such as an Ar gas atmosphere by, for example, DC magnetron sputtering at a deposition rate higher than 2 nm/s or at an atmospheric gas pressure lower than 2.66 Pa. By thus setting the deposition rate or the atmospheric gas pressure, it is possible to form the polycrystalline first underlayer 21 of the above-described crystal grains 21a and grain boundary part 21b. The deposition rate is preferably lower than or equal to 8 nm/s in terms of good controllability of film thickness at the time of forming the second underlayer 14. Further, the atmospheric gas pressure is preferably higher than or equal to 0.26 Pa in terms of stability of the plasma discharge of the sputtering apparatus. At the time of forming the first underlayer 21, it is preferable to apply no heat to the substrate 11 for the same reason as in the above-described case of the perpendicular magnetic recording medium 10 of the first example.

At the time of forming the first underlayer 21, a rarefied active gas may be supplied to the sputtering apparatus so that the molecules of the active gas may be adsorbed on the surface of the seed layer 13. Examples of the active gas include oxygen gas and N₂O. The amount of the adsorbed molecules of the active gas is such that the adsorbed molecules are separated from one another on the surface of the seed layer 13. As a result, the adsorbed molecules serve as the nuclei of growth of the crystal grains 21a of the first underlayer 21. With such nuclei of growth being formed, the crystal grains 21a start grain growth substantially simultaneously. Therefore, the crystal grains 21a are uniform in grain size. As a result, the uniform grain size is inherited to the second underlayer 14 and further to the recording layer 15, so that the recording layer 15 having a uniform grain size is formed.

Specifically, adsorption of the active gas on the surface of the seed layer 13 is preferably performed by exposing the surface of the seed layer 13 to the active gas in the range of less than 1 Langmuir (L). The Langmuir is a unit for exposure where 1 L signifies one-second exposure to an active gas of a pressure of 1×10⁻⁶ Torr.

The adsorbed molecules may convert the material of the seed layer 13 by oxidizing or nitriding the surface of the seed layer 13. Alternatively, the adsorbed molecules may simply be adsorbed on the surface of the seed layer 13. The surface of the seed layer 13 oxidized or nitrided by the adsorbed molecules or the adsorbed molecules themselves function as nuclei of grain growth.

In the perpendicular magnetic recording medium 20 of the second example, the first underlayer 21 of a continuous polycrystalline film formed of the crystal grains 21a and the grain boundary part 21b is provided between the seed layer 13 and the second underlayer 14. Since the first underlayer 21 is a continuous polycrystalline film, the first underlayer 21 has good crystal orientation. Accordingly, the crystal orientation of the crystal grains 14a of the second underlayer 14 is promoted by the first underlayer 21, so that the crystal orientation of the magnetic particles 15a of the recording layer 15 is further improved. As a result, magnetic characteristics such as perpendicular coercive force and rectangularity ratio are improved so as to increase reproduction output at high recording density, thus resulting in better recording and reproduction characteristics. Accordingly, it is possible to perform recording with higher density. The perpendicular coercive force is a coercive force obtained by applying a magnetic field in a direction perpendicular to a substrate surface and measuring the hysteresis loop of magnetization or Kerr rotation angle with a vibrating sample magnetometer or a Kerr effect measuring apparatus. Further, the rectangularity ratio is the ratio of the residual magnetization of the hysteresis loop to saturation magnetization (=residual magnetization÷saturation magnetization).

Further, the total film thickness of the first underlayer 21 and the second underlayer 14, that is, the sum of the film thickness of the first underlayer 21 and the film thickness of the second underlayer 14, can be less than the film thickness of the underlayer 14 in the case of the perpendicular magnetic recording medium 10 of the first example, so that the surface of the soft magnetic underlayer 12 can be closer to the surface of the lubricating layer 18. Accordingly, it is possible to reduce the head magnetic field strength required at the time of recording, and also to prevent side erasure.

Further, the second underlayer 14 of the perpendicular magnetic recording medium 20 of the second example can be smaller in film thickness than the underlayer 14 of the perpendicular magnetic recording medium 10 of the first example shown in FIG. 1. Therefore, the surface characteristic of the surface of the second underlayer 14 can be improved. Since the recording layer 15 and the protection film 16 inherit the surface characteristic of the second underlayer 14, the perpendicular magnetic recording medium 20 having a good surface characteristic can be realized. Accordingly, recording can be performed with higher density with a reduced space between a magnetic head and the perpendicular magnetic recording medium 20.

Next, a description is given of implementation examples according to the first embodiment.

### IMPLEMENTATION EXAMPLES 1 THROUGH 3

The perpendicular magnetic recording medium of Implementation Example 1 was provided with the same configuration as the perpendicular magnetic recording medium 20 of the second example shown in FIG. 3.

First, a CoZrNb film of 200 nm in film thickness and a Ta film of 3 nm in film thickness were formed in order on the surface of a Si substrate having an amorphous Si oxide film formed thereon at an atmospheric gas pressure of 0.399 Pa in an Ar gas atmosphere by sputtering.

Next, the Ru film of a first underlayer of 9 nm in film thickness was formed at an atmospheric gas pressure of 0.133 Pa and at a deposition rate of 0.6 nm/s in an Ar gas atmosphere by sputtering.

Next, the Ru film of a second underlayer of 15 nm in film thickness was formed at an atmospheric gas pressure of 5.32 Pa and at a deposition rate of 0.3 nm/s in an Ar gas atmosphere by sputtering.

Next, a CO₈₀Pt₂₀ film of 10 nm in film thickness was formed at a pressure of 5.32 Pa and at a deposition rate of 0.2 nm/s in an Ar gas atmosphere by sputtering.

Next, a carbon film of 3 nm in film thickness was formed by sputtering. No heat was applied to the Si substrate during the formation of the films from the CoZrNb film through the carbon film.

The perpendicular magnetic recording media of Implementation Examples 2 and 3 were formed in the same manner as that of Implementation Example 1 except that the film thickness of the Ru film of the second underlayer of Implementation Example 1 was changed to 20 nm and 25 nm in Implementation Examples 2 and 3, respectively.

For comparison, the perpendicular magnetic recording medium of a comparative example was formed in the same manner as that of Implementation Example 1 except that the Ru film of the second underlayer of Implementation Example 1 was omitted.

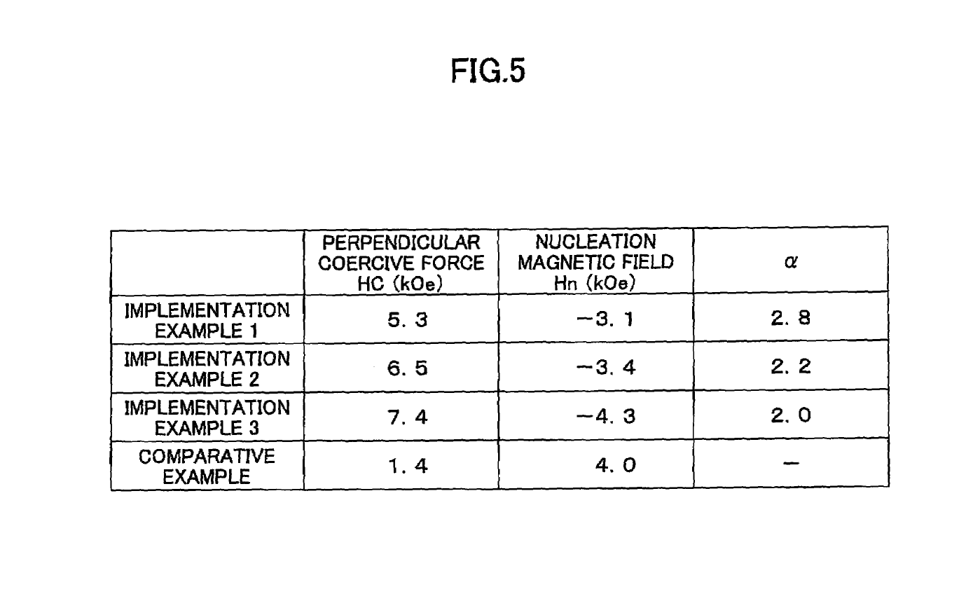

FIG. 5 is a table showing the magnetic characteristics of the perpendicular magnetic recording media of Implementation Examples 1 through 3 and the comparative example.

Referring to FIG. 5, in Implementation Examples 1 through 3, the perpendicular coercive force Hc significantly increases, and the nucleation magnetic field Hn is negative and its absolute value is large so that the hysteresis loop is closer to a rectangle, thus showing preferable magnetic characteristics compared with the comparative example. FIG. 5 shows that in Implementation Examples 1 through 3, with a thicker Ru film of the second underlayer, the perpendicular coercive force Hc is higher, and the hysteresis loop is closer to a rectangle.

Further, the α value showing the degree of the interaction between the magnetic particles of the recording layer is the inclination of a demagnetization curve at a position where the value of magnetization is 0. In the case of the comparative example, the demagnetization curve was not rectilinear at a position where the value of magnetization was 0, so that it was not possible to obtain the α value. This is because the recording layer is a continuous film of magnetic particles in close contact with one another in the comparative example. On the other hand, in Implementation Examples 1 through 3, the α value is approximately 2.0 to 2.8. This shows that the magnetic particles are separated from one another and the isolation of crystal grains is promoted.

Further, in Implementation Examples 1 through 3, the uniaxial anisotropy constant Ku is 1.15 erg/cm³. This shows that the Ku value of the Co₅₀Pt₅₀ recording layer of the conventional perpendicular magnetic recording medium, which recording layer is formed at a substrate heating temperature of, for example, 700° C., is obtained although there is no substrate heating under the manufacturing conditions.

Therefore, according to Implementation Examples 1 through 3 and the comparative example, it is shown that the magnetic particles of the recording layer are formed separately from one another by forming the second underlayer under the above-described conditions and forming the recording layer only of a ferromagnetic material without using oxide, etc. That is, it is shown that isolation in the recording layer is achieved in Implementation Examples 1 through 3.

The above-described hysteresis curves were obtained by measuring the relationship between the Kerr rotation angle and the applied magnetic field using a Kerr effect measuring apparatus. The applied magnetic field was perpendicular to the substrate surface.

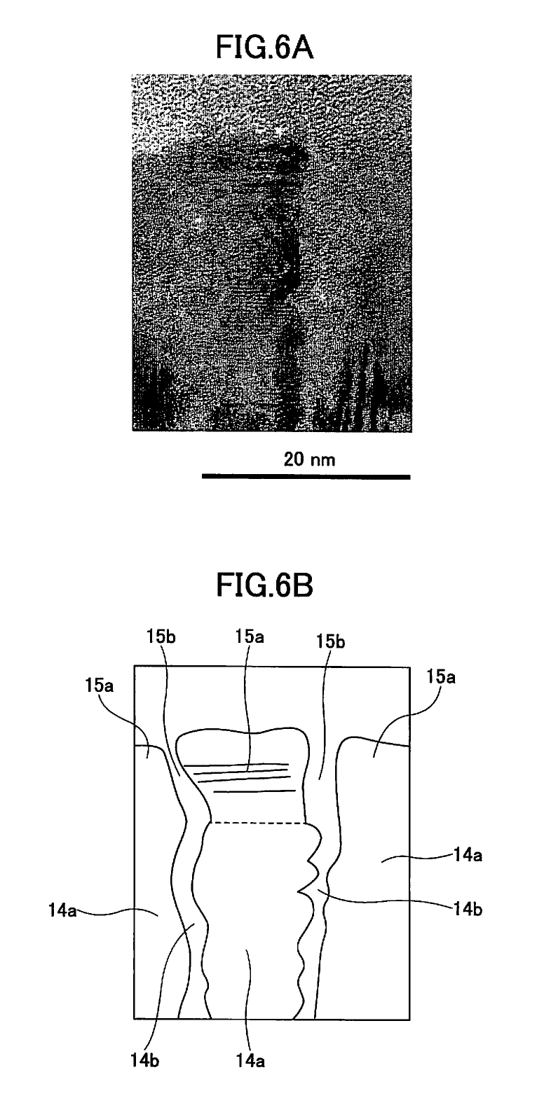

FIG. 6A is a cross-sectional TEM photograph of a perpendicular magnetic recording medium of an implementation example according to the first embodiment. FIG. 6B is a diagram for illustrating FIG. 6A.

FIGS. 6A and 6B show that one columnar crystal grain (formed of one of the crystal grains 14a of the underlayer 14 and a corresponding one of the magnetic particles 15a of the recording layer 15) has grown, being separated from other crystal grains (out of focus and blurry) by the air gap part 15b. The portion seen as filling in the space between the crystal grain and the other crystal grains is resin for sample fixation, and does not originate from the perpendicular magnetic recording medium.

### Second Embodiment

A second embodiment of the present invention relates to a magnetic storage unit including a perpendicular magnetic recording medium according to the first example or the second example of the first embodiment.

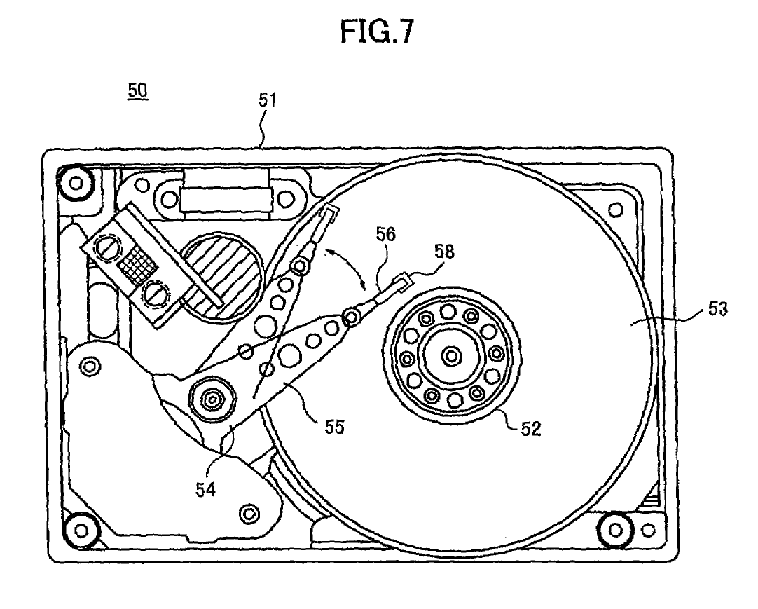

FIG. 7 is a diagram showing part of a magnetic storage unit 50 according to the second embodiment of the present invention. Referring to FIG. 7, the magnetic storage unit includes a housing 51. Further, the magnetic storage unit includes a hub 52 driven by a spindle (not graphically illustrated), a perpendicular magnetic recording medium 53 rotatably fixed to the hub 52, an actuator unit 54, an arm 55 and a suspension 56 attached to the actuator unit 54 so as to be movable in the radial directions of the perpendicular magnetic recording medium 53, and a magnetic head 58 supported by the suspension 56, which are provided in the housing 51.

The magnetic head 58 is formed of, for example, a single-pole recording head and a reproduction head including a GMR (giant magnetoresistive) element.

The single-pole recording head includes a main pole formed of a soft magnetic material for applying a recording magnetic field to the perpendicular magnetic recording medium 53, a return yoke magnetically connected to the main pole, and a recording coil for guiding a recording magnetic field to the main pole and the return yoke. The single-pole recording head forms perpendicular magnetization in the perpendicular magnetic recording medium 53 by applying a recording magnetic field in a direction perpendicular to the perpendicular magnetic recording medium 53 from the main pole.

Further, the reproduction head includes a GMR element. The GMR element can obtain information recorded in the recording layer of the perpendicular magnetic recording medium 53 by sensing as a change in resistance the direction of a magnetic field in which the magnetization of the perpendicular magnetic recording medium 53 leaks. A TMR (tunnel magnetoresistive) element may be used in place of the GMR element.

The perpendicular magnetic recording medium 53 is a perpendicular magnetic recording medium according to the first example or the second example of the first embodiment. Since the perpendicular magnetic recording medium 53 has a good SN ratio, the magnetic storage unit 50 capable of high-density recording is realized.

The basic configuration of the magnetic storage unit 50 according to the second embodiment is not limited to the one shown in FIG. 7. The magnetic head 58 is not limited to the above-described configuration, and may be replaced by a known magnetic head. Further, the perpendicular magnetic recording medium 53 employed in this embodiment is not limited to a magnetic disk, and may be a magnetic tape.

According to the second embodiment, the magnetic storage unit 50 is capable of high-density recording because the perpendicular magnetic recording medium 53 has a good SN ratio because of reduced medium noise. Further, the magnetic storage unit 50 is highly reliable since the surface of the recording layer of the perpendicular magnetic recording medium 53 is prevented from being contaminated by oxide, etc.

According to one aspect of the present invention, the crystal grains of an underlayer grow, being separated from one another by an air gap part, and the magnetic particles of the recording layer grow thereon. Therefore, the magnetic particles are disposed, being separated from one another. Therefore, it is possible to reduce medium noise by suppressing the magnetic interactions exerted between the individual magnetic particles. As a result, the SN ratio of the perpendicular magnetic recording medium is improved, thus enabling recording to be performed with still higher density. On the other hand, the magnetic particles of a recording layer are separated from one another by an air gap part. Accordingly, compared with the conventional perpendicular magnetic recording medium containing oxide, nitride, and/or oxynitride (in the specification, collectively referred to as “oxide, etc.”) in its recording layer, it is possible to realize a highly reliable perpendicular magnetic recording medium because it is possible to prevent the surface of the recording layer from being contaminated by oxide, etc. Further, the perpendicular magnetic recording medium makes it possible to prevent a decrease in the production yield due to the material of the recording layer.

Another underlayer may be provided between the substrate and the underlayer, and the other underlayer may be formed of a polycrystalline film of crystal grains of Ru or a Ru alloy coupled to each other through a grain boundary part. The other underlayer formed of the crystal grains of Ru or a Ru alloy and the grain boundary part is provided between the substrate and the underlayer. Since the other underlayer is a continuous polycrystalline film, the other underlayer has good crystallinity and crystal orientation. This promotes the crystal orientation of the crystal grains of the underlayer, thus further improving the crystal orientation of the magnetic particles of the recording layer. As a result, magnetic characteristics such as perpendicular coercive force and rectangularity ratio are improved so as to increase reproduction output at high recording density, thus resulting in better recording and reproduction characteristics. Accordingly, it is possible to perform recording with higher density.

According to one aspect of the present invention, a granular structure is formed in a recording layer without using a non-magnetic material such as oxide. Therefore, a film formation chamber is prevented from being contaminated by oxide, etc. Accordingly, the surface of the recording layer is prevented from being contaminated by oxide, etc., so that it is possible to avoid a decrease in the yield in a surface defect inspection of perpendicular magnetic recording media. Accordingly, it is possible to avoid a decrease in the production yield. Further, since it is possible to prevent the surface of the recording layer from being contaminated by oxide, etc., it is possible to provide a highly reliable perpendicular magnetic recording medium.

Thus, according to embodiments of the present invention, it is possible to provide a perpendicular magnetic recording medium capable of improving the SN ratio, avoiding a decrease in the production yield, and improving the reliability of a magnetic storage unit; a method of manufacturing the same; and a magnetic storage unit including the same.

The present invention is not limited to the specifically disclosed embodiments, and variations and modifications may be made without departing from the scope of the present invention.

What is claimed is:

1. A perpendicular magnetic recording medium, comprising:
a substrate;
an underlayer formed of one of Ru and a Ru alloy on the substrate; and
a recording layer formed on the underlayer,
wherein the underlayer includes a plurality of crystal grains extending in a direction perpendicular to a surface of the substrate, the crystal grains being separated from each other by a first air gap part; and
the recording layer includes a plurality of magnetic particles deposited on the crystal grains of the underlayer, the magnetic particles being separated from each other by a second air gap part.

2. The perpendicular magnetic recording medium as claimed in claim 1, wherein the first air gap part and the second air gap part are formed so as to communicate with each other.

3. The perpendicular magnetic recording medium as claimed in claim 1, wherein an average grain size of the crystal grains is in a range of 2 nm to 10 nm.

4. The perpendicular magnetic recording medium as claimed in claim 1, wherein a film thickness of the underlayer is in a range of 2 nm to 30 nm.

5. The perpendicular magnetic recording medium as claimed in claim 4, further comprising:
a seed layer between the substrate and the underlayer,
wherein the seed layer is formed of at least one selected from the group consisting of Ta, Ti, C, Mo, W, Re, Os, Hf, Mg, Pt, and alloys thereof, or is formed of NiP.

6. The perpendicular magnetic recording medium as claimed in claim 1, further comprising:
an additional underlayer between the substrate and the underlayer,
wherein the additional underlayer is formed of a polycrystalline film of crystal grains of one of Ru and a Ru alloy coupled to each other through a grain boundary part.

7. The perpendicular magnetic recording medium as claimed in claim 6, further comprising:
a seed layer between the substrate and the additional underlayer,
wherein the seed layer is formed of at least one selected from the group consisting of Ta, Ti, C, Mo, W, Re, Os, Hf, Mg, Pt, and alloys thereof, or is formed of NiP.

8. The perpendicular magnetic recording medium as claimed in claim 1, wherein:
the Ru alloy is a Ru—X alloy having an hcp crystal structure, where X is at least one selected from the group consisting of Co, Cr, Fe, Ni, and Mn.

9. The perpendicular magnetic recording medium as claimed in claim 1, wherein:
the magnetic particles of the recording layer are formed of one ferromagnetic material selected from the group consisting of Ni, Fe, Co, Ni-based alloys, Fe-based alloys, CoCr, CoPt, and CoCr alloys.

10. The perpendicular magnetic recording medium as claimed in claim 1, wherein:
the magnetic particles of the recording layer are formed of one ferromagnetic material selected from the group consisting of CoCr, CoCrTa, CoPt, CoCrPt, and CoCrPt-M, where M is formed of at least one material selected from the group consisting of B, Mo, Nb, Ta, W, Cu, and alloys thereof.

11. A magnetic storage unit, comprising:
a recording and reproduction part including a magnetic head; and
the perpendicular magnetic recording medium as set forth in claim 1.

12. A method of manufacturing a perpendicular magnetic recording medium, comprising the steps of:
(a) forming an underlayer on a substrate; and
(b) forming a recording layer on the underlayer,
wherein said step (a) forms the underlayer by sputtering at a deposition rate lower than or equal to 2 nm/s and at an atmospheric gas pressure higher than or equal to 2.66 Pa using a sputtering target of one of Ru and a Ru alloy; and
said step (b) deposits only a material formed of a ferromagnetic material.

13. The method as claimed in claim 12, wherein the deposition rate is higher than or equal to 0.1 nm/s in said step (a).

14. The method as claimed in claim 12, wherein the atmospheric gas pressure is lower than or equal to 26.6 Pa in said step (a).

15. The method as claimed in claim 12, further comprising the step of:
(c) forming a soft magnetic underlayer on the substrate before said step (a),
wherein a temperature of the substrate is lower than or equal to 150° C. in and before said step (b) after said step (c).

16. The method as claimed in claim 12, further comprising the step of:
(c) forming a soft magnetic underlayer on the substrate before said step (a),
wherein heat is prevented from being applied to the substrate in and before said step (b) after said step (c).

17. The method as claimed in claim 12, further comprising the step of:
(c) forming an additional underlayer on the substrate before said step (a),
wherein said step (c) forms the additional underlayer by sputtering at a deposition rate higher than 2 nm/s or at an atmospheric gas pressure lower than 2.66 Pa using a sputtering target of one of Ru and a Ru alloy.

18. The method as claimed in claim 17, wherein:
the deposition rate is higher than or equal to 8 nm/s in said step (c).

19. The method as claimed in claim 17, wherein:
the atmospheric gas pressure is higher than or equal to 0.26 Pa in said step (c).

20. The method as claimed in claim 12, wherein:
said step (b) forms the recording layer by sputtering in an inert gas atmosphere using a sputtering target formed of a ferromagnetic material.
